(19) United States
(12) Patent Application Publication
(10) Pub. No.: US 2023/0063446 A1
(43) Pub. Date: Mar. 2, 2023

(54) ETCH-FREE ULTRAFAST FABRICATION OF SELF-ROLLED METALLIC NANOSHEETS WITH CONTROLLABLE TWISTING

(71) Applicant: City University of Hong Kong, Hong Kong (HK)

(72) Inventors: Yong YANG, Hong Kong (HK); Tianyu WANG, Hong Kong (HK); Minhyuk PARK, Hong Kong (HK); Zhibo ZHANG, Hong Kong (HK)

(21) Appl. No.: 17/462,106

(22) Filed: Aug. 31, 2021

(51) Int. Cl. C23C 14/00; C23C 14/02; C23C 14/20; C23C 16/01; C23C 16/02; C23C 16/06

(52) U.S. Cl. CPC C23C 14/0005; C23C 14/024; C23C 14/20; C23C 16/01; C23C 16/0272; C23C 16/06

(57) ABSTRACT

The present invention provides a method of forming a self-rolled metallic nanosheet. The method includes providing a bendable polymeric substrate and forming a hydrogel-based separation layer on the bendable polymeric substrate. A thin-film metallic nanosheet is deposited on the hydrogel-based separation layer, the thin-film metallic nanosheet having a thickness of approximately 150 nm or less to form a nanosheet-hydrogel-polymer composite. Channel cracks are induced in the nanosheet-hydrogel-polymer composite. The hydrogel layer is swelled to delaminate the metallic nanosheet employing the induced channel cracks to form one or more nano-morphology structures selected from scroll morphology, ribbon morphology, spiral morphology, or helix morphology.

### FIELD OF THE INVENTION

The present invention relates to metallic nanosheets and, more particularly to sell-rolling nanosheets with controllable twisting.

### BACKGROUND

Since 2000, self-rolling of planar sheets into tubes or helices has been attracting tremendous research interest because of their potential applications in biomedical engineering, micro-robots and optical engineering. In recent years, self-rolling of thin films and atomically thin layers (2D materials), such as graphene and WSe₂, is considered as a novel method—even being termed as the “roll-up” technology in the literature—for the development of important micro- and nano-devices, such as microgripper, micromotors, resonators, micro-inductors and a variety of Van der Waals (vdW) heterostructures.

Conventional “roll-up” technology is mainly based on a wet etching technique, which causes peel-off and subsequent self-rolling of a nanosheet by etching away an inorganic sacrificial layer fabricated via molecular beam epitaxy (MBE)—such as AlAs and Si—between the nanosheet and its underlying silicon substrate in a hydrogen fluoride (HF) solution. However, wet etching of the sacrificial inorganic layer is slow, usually at an etching speed of ˜10 nm/s. Consequently, conventional wet etching-based “roll-up” technology has a rather low efficiency, and it takes hours and even days for such a self-rolling process to complete. In 2008, Mei et al. (Adv. Mater. 2008, 20 (21), 4085-4090) utilized an organic sacrificial layer fabricated through photolithography on a silicon substrate for wet etching in acetone. As a result, the etching speed was increased to ˜1 μm/s. Furthermore, it is required for the wet etching methods that the nanosheets are not chemically reactive in the etching solution; additionally, the nanosheets must be as stretchable as possible such that these nanosheets can withstand a large strain during the dissolution of the sacrificial layer. These stringent requirements limit the broad application of the etching method. Therefore, there is a need for a new fabrication method that can overcome the above shortcomings.

### SUMMARY OF THE INVENTION

The present invention provides a method to fabricate selected nanostructure morphologies, e.g., tubular microstructures with controlled twisting, by rolling up large-sized metallic nanosheets. Compared to the prior methods, the method of the present invention does not use the dissolution of a sacrificial layer as in wet etching. Instead, it is based on the swelling and surface buckling of a hydrogel intermediate layer sandwiched between a metallic nanosheet and a soft polymeric substrate. As a result, the method does not use any corrosive chemicals and is considerably faster (with an average peeling speed of 40 μm/s) than conventional wet etching methods. Therefore, it can be applied to a wide range of materials with high efficiency.

In one aspect, the present invention provides a method of forming a self-rolled metallic nanosheet. The method includes providing a bendable polymeric substrate and forming a hydrogel-based separation layer on the bendable polymeric substrate. A thin-film metallic nanosheet is deposited on the hydrogel-based separation layer, the thin-film metallic nanosheet having a thickness of approximately 150 nm or less (150 nm maximum) to form a nanosheet-hydrogel-polymer composite. In one aspect, a thickness of about 60 nm is selected. Channel cracks are induced in the nanosheet-hydrogel-polymer composite. The hydrogel layer is swelled to delaminate the metallic nanosheet employing the induced channel cracks to form one or more nano-morphology structures selected from scroll morphology, ribbon morphology, spiral morphology, or helix morphology.

### BRIEF DESCRIPTION OF THE DRAWINGS

FIG. 1a shows a method of forming self-rolled metallic nanosheets according to an embodiment including metallic micro-scrolls, micro-helices and micro-ribbons.

FIGS. 1b-1d are optical images showing the fabricated Ti scrolls, Ti helices and TiAlV ribbons floating in deionized water.

FIGS. 2a-2c are SEM images of as-fabricated scrolls, helices, and ribbons; the insets show the corresponding low-magnification images.

FIG. 2d is the AFM height image of the Ti nanosheet that was rolled up into the scrolls shown in 2a; the inset shows the line scan across the Si substrate and the Ti nanosheet.

FIG. 2e is a low magnification TEM image and FIG. 2f is a high resolution TEM image of the Ti nanosheet. The inset in FIG. 2e shows the corresponding selected area diffraction pattern and in 2f shows the fast Fourier transformation (FFT) image.

FIGS. 2g-i show the variation of the rolling diameter and channel crack spacing S with the nanosheet thickness for Ti (FIG. 2g). Cr (FIG. 2h), and TiAlV (FIG. 2i).

FIG. 3a shows formation of the scroll through the self-rolling of the nanosheet in the direction perpendicular to its long edge.

FIG. 3b is a set of bright-field optical images showing the rapid formation of scrolls via self-rolling of the Ti nanosheet.

FIG. 3c illustrates the process of forming helices via twisting.

FIG. 3d shows dark field optical images showing the formation of helices via rolling-twisting (T stands for a twist).

FIG. 3e is a sketch for the geometry of the twist that leads to the formation of a helix.

FIG. 3f is the measured helix length Lₜ as a function of time.

FIG. 3g is the calculated twisting angle as a function of time.

FIGS. 4a-4c show the results of a finite element (FE) study on the roll-up of rectangular films based on a line-constraint model.

FIG. 4a is the plot of the driving force ΔE and energy barrier ΔE* as a function of the et.

FIG. 4b is the variation of the energy barrier ΔE* with an increasing εₜ for nanosheets with fixed US value but different S.

FIG. 4c is the plot of the ΔE* as a function of D/S obtained with different S and US values.

FIG. 5 is a plot of the geometric data (D/S versus US) of the self-rolled nanosheets with different twisting angles. Note that the “squares” stand for the Ti nanosheets, the “diamonds” for the TiAlV nanosheets and the “circles” for the Cr nanosheets.

FIG. 6a is an optical image of the cross section of a polyimide membrane used in the method of the invention; FIG. 6b is a photo of the membrane (6 cm×6 cm); FIG. 6c is a line scan across the polyimide membrane and a PVA hydrogel;

FIGS. 7a-7d show an illustration of a line constraint applied to the model;

FIG. 8 is the calculated profiles of the roll-up nanosheets with the same in-depth strain (εₜ) and geometry (US ratio) but different crack spacing (S);

FIG. 9 is the calculated profiles of the roll-up nanosheets with the same crack spacing (S) and in-depth strain (εₜ) but different geometry (US ratio);

FIG. 10 is the variation of rolling diameter (D) as a function of in-depth strain obtained from both the FE simulation and the theoretical calculation;

FIGS. 11a-11c show optical images of TiAlV nanosheets rolled up with different geometries. The insets are the corresponding optical images of the nanosheets before being immersed in water. The scale bar in the insets is 50 μm (FIG. 11a), 300 μm (FIG. 11b) and 300 μm (FIG. 11c), respectively.

FIG. 12a-FIG. 12c show the variation of D/S with the nanosheet thickness for Ti (FIG. 12a), Cr (FIG. 12b) and TiAlV (FIG. 12c).

### DETAILED DESCRIPTION

Mechanistically, the self-rolling of a nanosheet is triggered by the release of an in-depth residual stress gradient. To develop such a residual stress gradient, a double- or multi-layer structure has been used in the prior art design and modeling of self-rolled sheets. According to the prior art, the in-depth profile of the residual stress gradient in a film deposited on a given substrate, which is to be rolled up upon peel-off, is often bi-axial and correlated with the deposition rate, the substrate temperature and the microstructure of the film and substrate. From a thermodynamic viewpoint, the self-rolling of a nanosheet is energetically favored because of energy minimization, which occurs always along a roll-up direction that seeks the lowest Gibbs free energy of the whole system; however, nanosheet self-rolling is also rate dependent, the kinetics of which depends on how a film peels off from a substrate. In practice, the morphology of a self-rolled sheet varies from scrolls to helices, which depends on the residual stress profile, the sheet geometry and the rolling direction. In the prior art, the same flat nanosheet may roll up either to a ‘tube’ structure or to a twisted helix structure.

The present invention provides a method of forming a self-rolled metallic nanosheet in which the nanosheet may be separated from the underlying layer without a chemical etching process being employed. To this end, the invention uses a swellable hydrogel layer beneath a deposited nanosheet. Swelling of the hydrogel layer causes delamination of the nanosheet, which includes channel cracks such that the delaminated nanosheet forms a variety of nanostructures.

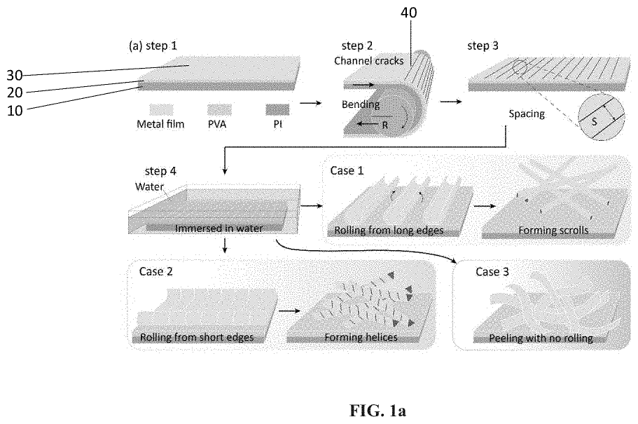

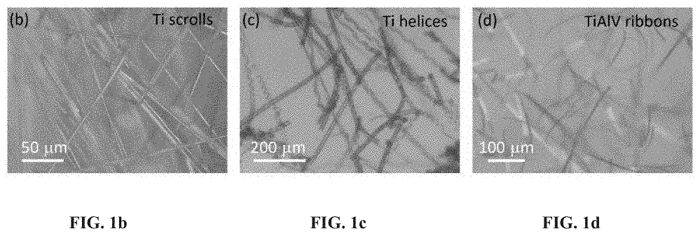

Turning to FIG. 1a, the method includes providing a bendable polymeric substrate 10. A wide variety of substrates may be selected as long as the polymer may be formed in a sheet, can withstand large bending deformation. and is compatible with subsequently-formed layers. Exemplary polymeric substrates 10 include polyimide substrates, polyethylene terephthalate substrates, nylon substrates, polyethylene substrates, polytetrafluoroethylene, acrylonitrile butadiene styrene (ABS), polylactide (PLA). The polymeric substrate 10 must be thin enough to be flexible and bendable. A thickness of approximately 125 microns or less may be used.

A hydrogel-based separation layer 20 is formed on the bendable polymeric substrate. As used herein, the term “hydrogel” relates to hydrophilic polymers, typically crosslinked polymers, that are swellable when immersed in water. The hydrogel may be deposited in the form of a solution followed by drying. Solution application methods such as spin-coating, doctor-blade coating, roll coating, spraying may be used for depositing the hydrogel. A variety of hydrogels may be used as layer 20 including, but not limited to, polyvinyl alcohol, silicone hydrogels, cellulose hydrogels, and acrylate hydrogels. Alternatively, a layer of dry hydrogel 20 may be laminated to the polymeric substrate 10. The thickness of the hydrogel layer should be relatively thin; for example, thicknesses on the order of approximately 300 nm to 5 microns may be used.

A thin film metallic nanosheet 30 is deposited on the hydrogel-based separation layer 20. Nanosheet 30 is extremely thin, on the order of approximately 10-200 nm. A variety of selected metals and metal alloys may be selected including titanium, titanium alloys, aluminum, aluminum alloys, vanadium, vanadium alloys, chromium, chromium alloys, ZiCuAlNi metallic glass, FeCoNiCrNb high entropy alloys. The nanosheet 30 may be deposited by a variety of thin film techniques including, but not limited to sputtering, magnetron sputtering, e-beam evaporation, chemical vapor deposition, or plasma-enhanced chemical vapor deposition.

Following creation of the nanosheet-hydrogel-polymer substrate composite, channel cracks 40 are inducted in the nanosheet layer. As used herein, the term “channel cracks” relates to a crack oriented substantially perpendicular to the nanosheet surface and extending through to the nanosheet-hydrogel interface. Along the in-plane direction, the crack would propagate perpendicular to the tensile stress exerted in the nanosheets. A variety of techniques may be used to induce channel cracks. In one embodiment, the nanosheet-hydrogel-polymer substrate composite is bent over a roller having a selected radius depending on the desired density and spacing of the channel cracks. The induced channel cracks are a series of parallel cracks with an inter-crack spacing of S that is directly proportional to the radius of the roller R and the thickness of the nanosheet. In other embodiments, channel cracks may be induced through cutting with a blade or pressing with a mold having desired crack spacing (nanoimprinting). Laser engraving may also be employed. However, any technique that induces channel cracks in the nanosheet may be used in the process of the present invention.

Following inducing of channel cracks, the hydrogel layer 20 is swelled to delaminate the nanosheet 30 from the nanosheet-hydrogel-polymer substrate composite. Swelling of hydrogel layer 20 may be accomplished by adding water to the layer, typically through immersion in water. Alternatively, water may be added by spraying the composite with water to swell the hydrogel layer. The metallic nanosheet is delaminated/displaced from the hydrogel layer due to the swelling to form one or more structures having the same or different nanomorphology. In particular, scroll morphologies, helical morphologies, ribbon morphologies may be formed. When using water immersion as the delamination technique, the peeling-off speed for the nanosheet is on the order of 40 μm/s. The delaminated nanosheet may roll laterally from the long edge of the three-layer composite forming cylindrical scrolls (case 1 in FIG. 1a), or may roll from the short edge forming helices (case 2 in FIG. 1a). Alternatively, it may delaminate without rolling depending on the film stresses to form ribbons (case 3 in FIG. 1a). When using water immersion, the delaminated structures are harvested from the water and dried.

### Example

### Overview

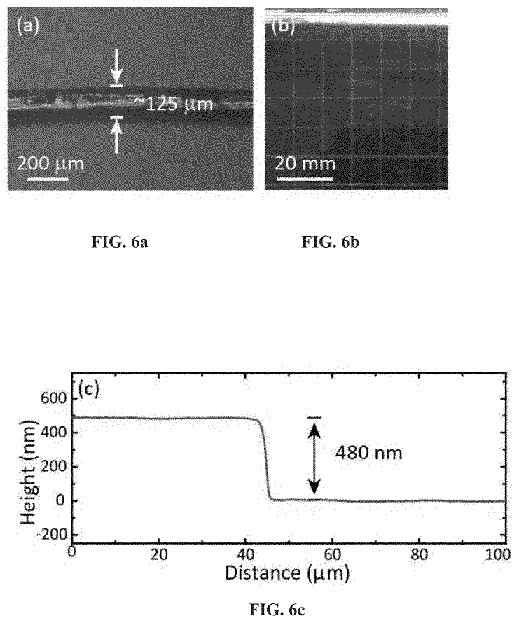

(1) Spin-coat a polyvinyl alcohol (PVA) hydrogel layer with the in-plane size of ˜6 cm×6 cm and a thickness of ˜500 nm on a 125 μm thick polyimide (PI) membrane. See FIGS. 6a and 6b which depict the polyimide membrane The PVA used was commercial (0588-type commercial PVA powder of 3 wt %-20 wt % dissolved in deionized water). The spinning speed ranges from 1k rpm to 8k rpm (rpm stands for round per minute). The as-spun PVA film is dried in an oven for at least 15 min with a temperature of approximately 40-70° C. to form a layer of PVA membrane on the PI membrane. FIG. 6c is a line scan across the polyimide membrane and the PVA hydrogel.

(2) Deposit a metallic film on the PVA-PI substrate through e-beam evaporation that has the in-plane size of ˜6 cm and thickness of 10 to 80 nm. Films include titanium and a titanium alloy, TiAlV. During film deposition, the temperature of the PVA membrane should be maintained lower than approximately 80° C. to avoid physical change of the PVA material. The thickness of the deposited thin film is smaller than approximately 150 nm. Following deposition, the composite metallic nanosheet-PVA-PI substrate is maintained in a low-humidity environment.

(3) Bend the metal-PVA-PI tri-layer over a roller with radius R that ranges from 1.25 mm to 10 mm to generate parallel channel cracks in the metallic film, the spacing (S) of which can be controlled through selection of the roller radius size and film thickness. Channel cracks in the nanosheet are introduced either by direct bending the composite or through rolling over a bar with fixed radius RB. The spacing of the channel cracks is further controlled by modulus ratio between the metallic nanosheet and the PVA, the ratio of the fracture toughness, as well as the stress level of the metallic nanosheet. The length of the channel crack can roughly control the final length of the microscrolls.

(4) Immerse the channel-crack-containing metal-PVA-PI tri-layer in deionized water to delaminate the metallic nanosheet from the PVA-PI substrate with the metallic nanosheet as a top surface facing upward.

Three types of structures form based on the stress level and geometry of the film: helices or scrolls are formed if the metallic nanosheet layer has in-depth strained gradient while ribbons are formed if the metallic nanosheet layer is not strained. Further, it is more likely to form helices if the crack spacing is finer than the typical rolling diameter of the film.

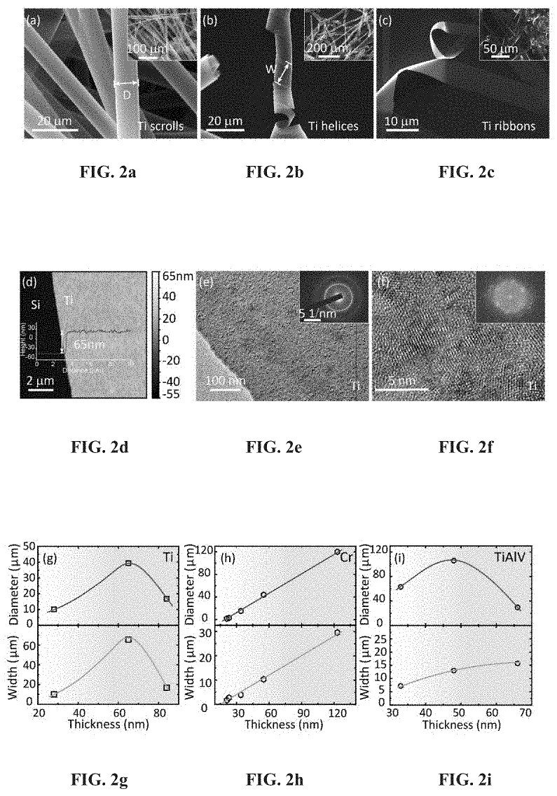

Self-rolled nanosheets with various nanomorphologies are depicted in FIG. 1b-Id and FIGS. 2a-2c. FIGS. 1b and 2a depict titanium scrolls, FIGS. 1c and 2b depict titanium helices, and FIGS. 1d and 2c depict TiAlV ribbons and Ti ribbons, respectively. Notably, the surfaces of the rolled-up nanosheets (shown in FIGS. 2d, 2e, and 2f) are smooth and free of any contamination due to the use of water for delamination rather than an etchant. FIG. 1d shows the typical height image of the Ti metallic nanosheet obtained from atomic force microscopy (AFM), which has a thickness of 65 nm and a room-mean square (RMS) roughness of 3.6 nm. Similar results were obtained from other metallic nanosheets fabricated using the method of the present invention. Furthermore, transmission electron microscopy (TEM) examination was carried out on the titanium nanosheet, which exhibited nanocrystalline hexagonal close packing (HCP) FIG. 2e. 2f. The diameter D of the scrolls and helices was measured at different thicknesses (h) (FIG. 2g. FIG. 2h. FIG. 2i) and channel crack spacing (S) for three classes of metallic nanosheets (Ti. Cr. TiAlV). The channel crack spacing S varies with the nanosheet thickness h in a similar manner as the diameter (D) does with h (FIG. 2g-2i). For Ti and TiAlV, the diameter rises and then declines with h; while for Cr, the diameter increases with h. Channel crack spacing S has been previously shown to increase linearly with \sqrt{h} but decreases with the in-depth residual strain co. Since S scales with the diameter of the scrolls and helices, this suggests that the diameter of the scrolls/helices is determined not only by the nanosheet thickness (h) but also by the residual stress in the metallic nanosheet before delamination.

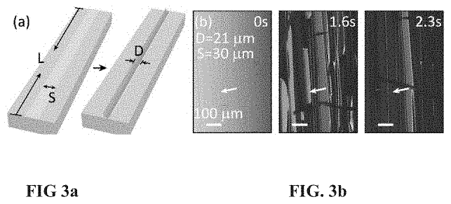

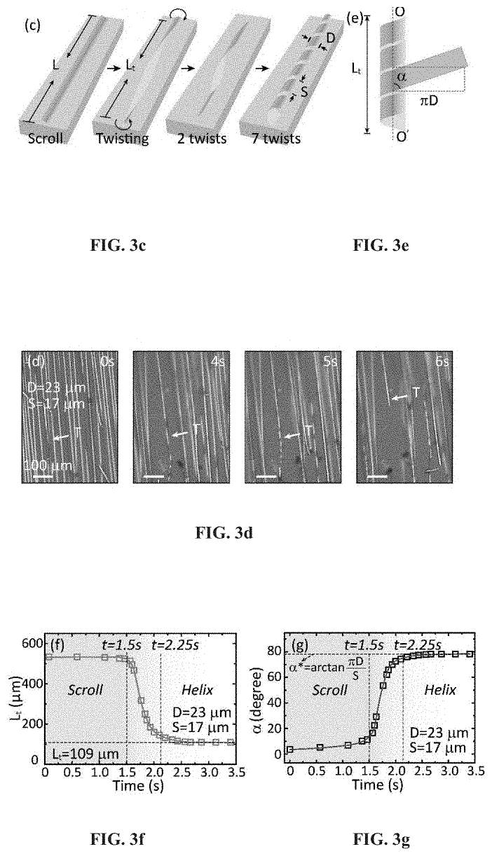

It is known that sometimes substantially similar metallic nanosheets that have been subjected to similar process conditions may alternately roll into a scroll or a helix. As shown in FIGS. 3a-3b the nanosheet of width S (equal to the channel crack spacing) and length L peels off from its long edge from the hydrogel surface after being immersed in water and rolls very rapidly into a long scroll afterwards. In contrast, as illustrated in FIGS. 3c and 3d the same nanosheet could twist on its own and finally form a helix. If the twisting angle α is defined as the angle between the long edge of the nanosheet and the central axis of rolling (OO′) (see FIG. 3e), the following relation between a and the length Lₜ of the helix is defined as:

$$α = arccos \frac{{L}_{t}}{L} \qquad ( 1 )$$

In practice, Lₜ may be measured by tracking the propagation of the twist along the longitudinal axis of the self-rolled nanosheet (FIG. 3d). With the measured Lₜ, α can be backed out using Equation (1). FIG. 3f shows the experimental data of Lₜ versus time obtained from a titanium nanosheet with S=17 μm and L=530 μm. At the beginning of rolling, Lₜ remains almost unchanged until the time lapse reaches 1.5 s. After that. Lₜ drops sharply within 1 second and levels off to a constant value of ˜109 μm. Accordingly, the twist angle α rises from ˜0 to ˜71 degrees and approaches a constant value of 78 degrees (FIG. 3g). This value is very close to the theoretical twist angle at which two adjacent twists are just in contact and therefore become self-hindered:

$${α}^{*} = arctan \frac{π D}{S} \qquad ( 2 )$$

Taking D=23 μm and S=17 μm, it is estimated that α* is equal to 76.8 degrees.

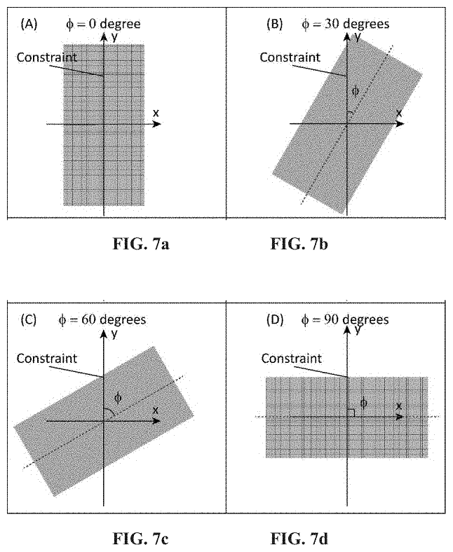

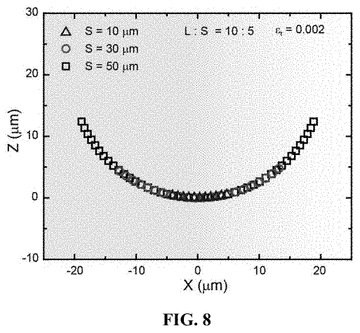

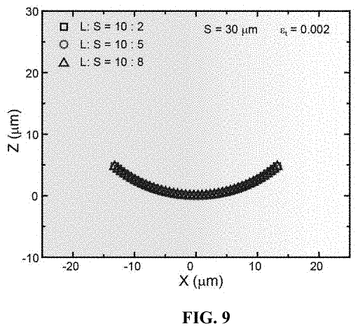

To gain quantitative insights into the phenomenon of rolling-and-twisting, extensive finite element (FE) simulations were performed with double-layer shell elements (Shell181. ANSYS®) to emulate the self-rolling of a nanosheet in the presence of a stress gradient. The top layer was assigned with a thermal expansion coefficient of 2.5×10⁻⁴ K⁻¹ while the bottom one with 1×10⁻¹⁰ K⁻¹. The out-of-plane displacement of the elements along the prescribed rolling axis that defines the twist angle ϕ was fixed (see FIG. 7a-7d). The temperature was systematically reduced in the FE simulations and, as a result of the thermal stress mismatch, the FE model rolled up into different morphologies with different ϕ values as demonstrated. Roll-up morphologies were obtained from FE simulation with different constrained angle ϕ. Note that the top layer strain εₜ and the aspect ratio US equaled to 0.08% and 10:3, respectively and a color map represents the out-of-plane deformation.

The elastic energy as a function of the twist angle ϕ (or elastic energy landscape) was obtained from the rolled-up nanosheet with an aspect ratio of 3:10 and a maximum in-depth strain of 0.08%. Evidently, the global energy minimum occurs at the longitudinal rolling (ϕ=90 degrees) with the local minimum at the lateral rolling (ϕ=0 degrees). From the thermodynamic viewpoint, the longitudinal rolling is more energetically favorable than the lateral rolling. However, lateral rolling is faster than longitudinal rolling and hence, occurs in the first place. In such a case, there is always a tendency for the lateral rolling to transit to the longitudinal rolling through twisting. This is demonstrated in the twisting of the nanosheets in some embodiments. Nonetheless, this configurational transition can be interrupted at any intermediate twisting angle because of the self-hinderance of the twists (Eq. 2). The energy barrier ΔE* and the driving force ΔE can be calculated for the configurational transition.

The elastic energy landscape depends on the original geometry of the nanosheet. The calculated elastic energies vary with the aspect ratio of the nanosheet. The variation of elastic energy profiles G is normalized by G* with an increasing top layer strain et. The aspect ratio US here equals 2.

For comparison, all calculated elastic energies are normalized by the elastic energy G* that corresponds to the respective longitudinal rolling (ϕ=90 degrees). As the aspect ratio of the nanosheet reaches 1:1, there is no essential difference between lateral and longitudinal rolling. In this case, two metastable helical configurations emerge at ϕ=30 and ϕ=60 degrees respectively, indicative of the scenario of “multi-stability” Such a near-diagonal rolling with ϕ=30 or 60 degrees has been experimentally observed but not fully understood yet, which however supports the FE simulations. Aside from the geometry of the nanosheet, the level of the maximum strain εₜ across the nanosheet thickness also affects the elastic energy landscape. An evolution of a G/G*-ϕ curve with the aspect ratio (US) of the nanosheets is plotted. Although the elastic energy landscape remains similar in shape, the normalized driving force ΔE/G* drops with et.

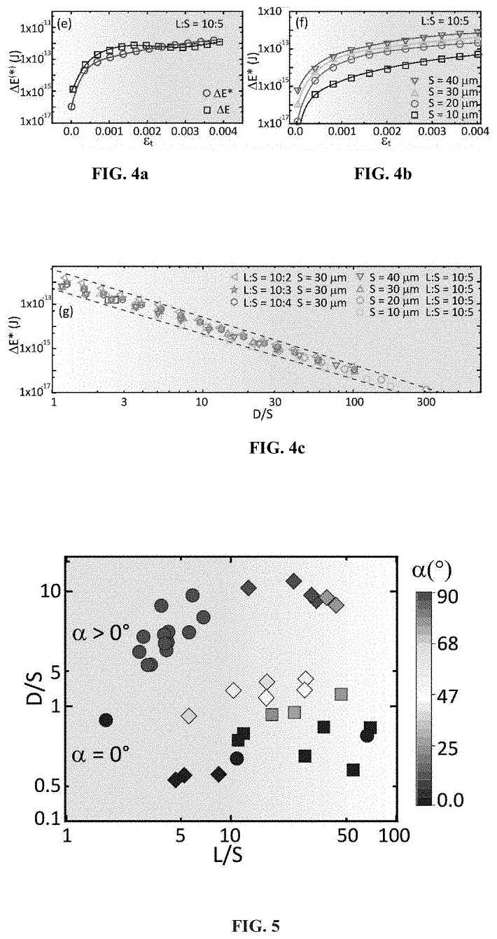

FIG. 4a shows the variation of the energy barrier ΔE* and the driving force ΔE with εₜ for a given aspect ratio of the nanosheet. Notably, both ΔE* and ΔE increase with εₜ but level off to a constant value after et reaches 0.2%. According to the statistical mechanics, the rate of the configurational transition is a multiplication of the kinetic factor

$$exp ( - \frac{Δ {E}^{*}}{{k}_{B} T} )$$

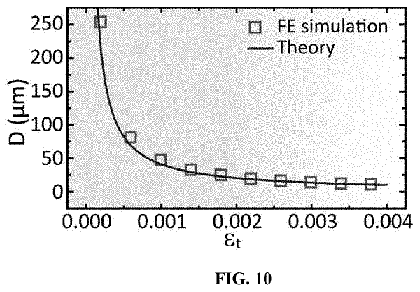

by the thermodynamic factor

$$[ 1 - exp ( - \frac{Δ E}{{k}_{B} T} ) ] ,$$

where k_{B} is the Boltzmann constant and T the temperature. Since ΔE* (>1×10⁻⁷ J) and ΔE (>1×10⁻⁵ J) are much larger than k_{B}T (˜4.2×10⁻² J at T=300 K), the thermodynamic factor is very close to unity and the rate of the configurational transition is mainly controlled by the kinetic factor. Therefore, the increasing ΔE* with et suggests that twisting would become slow for high residual strains. In other words, highly strained nanosheets are more likely to keep lateral rolling because of the kinetic slow-down of twisting. The combined effect of et and S on the energy barrier ΔE* was further considered. As shown in FIG. 4b, the curve of ΔE* versus et is shifted upwards with the increasing S value for the given aspect ratio of the nanosheet. This behavior implies that the wider the nanosheet, the higher the energy barrier against the configurational transition. Here, it is worth noting that, according to the FE simulations, the rolling diameter D is irrelevant to the size (FIG. 8) and geometry (FIG. 9) of the nanosheet but decreases with the increasing et (FIG. 10). Interestingly, it appears that the data of ΔE* obtained at different values of US ratio (>2) and S can be collapsed onto the same master curve of ΔE* versus D/S, i.e., ΔE* decreases monotonically with D/S, as seen in FIG. 4c. This behavior implies that the D/S ratio may be considered as the dimensionless indicator of ΔE* when the US value is far away from unity.

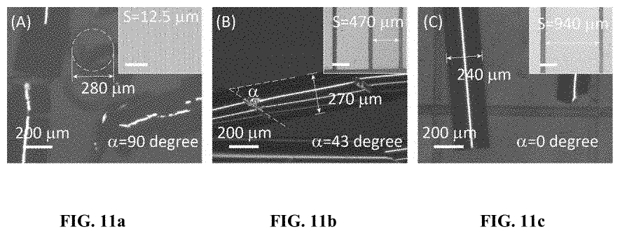

To validate the above predictions, the morphology, size, and geometry of a variety of self-rolled nanosheets was measured. The experimental results indicate that the nanosheets with the same D and L could roll into helices for small S, and into scrolls when S is comparable to or larger than D (see the example of the self-rolled TiAlV nanosheets in FIG. 11). As shown in FIG. 5, the self-rolled nanosheets tend to form scrolls through longitudinal rolling (α=0 degrees) for a small D/S ratio while transitioning to helices (0<α<90 degrees) and eventually back to scrolls through lateral rolling (α=90 degrees) as the D/S ratio increases. According to FIG. 4c, the larger the D/S ratio, the lower the ΔE*. In theory, reduction in ΔE* means that it is more kinetically feasible to form helices from the self-rolling of the nanosheets with a large D/S ratio, which agrees very well with the experimental observation.

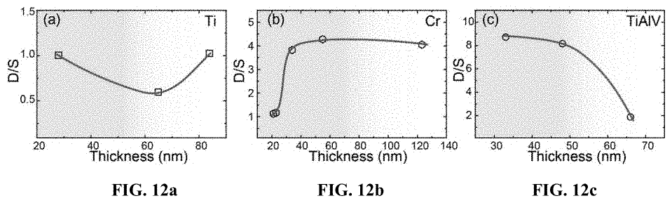

FIG. 12a-FIG. 12c show the variation of D/S with the nanosheet thickness for Ti (FIG. 12a), Cr (FIG. 12b) and TiAlV (FIG. 12c).

The present invention provides an ultrafast and etching free method to synthesize self-rolled nanosheets with controllable morphologies (scrolls and helices) through polymer surface buckling enabled exfoliation. The extensive FE simulations and experiments reveal that the seemingly complex configurational transitions (scroll-helix-scroll) are mainly controlled by the energy barrier, which can be correlated with the dimensionless D/S ratio.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A method of forming a self-rolled metallic nanosheet comprising:
providing a bendable polymeric substrate;
forming a hydrogel-based separation layer on the bendable polymeric substrate;
1. depositing a thin-film metallic nanosheet on the hydrogel-based separation layer, the thin-film metallic nanosheet having a thickness of approximately 150 nm or less to form a nanosheet-hydrogel-polymer composite;
inducing channel cracks in the nanosheet-hydrogel-polymer composite;
swelling the hydrogel layer to delaminate the metallic nanosheet employing the induced channel cracks to form one or more nano-morphology structures selected from scroll morphology, ribbon morphology, spiral morphology, or helix morphology.

2. The method of forming a self-rolled metallic nanosheet according to claim 1, wherein the bendable polymeric substrate is selected from polyimide, polyethylene terephthalate, nylon, or polyethylene.

3. The method of forming a self-rolled metallic nanosheet according to claim 1, wherein the hydrogel is selected from one or more of polyvinyl alcohol, silicone hydrogels, cellulose hydrogels, acrylate hydrogels, agarose, or chitosan.

4. The method of forming a self-rolled metallic nanosheet according to claim 1, wherein the metallic nanosheet is selected from titanium, titanium alloys, aluminum, aluminum alloys, vanadium, vanadium alloys, chromium, or chromium alloys.

5. The method of forming a self-rolled metallic nanosheet according to claim 1, wherein the metallic nanosheet is deposited by vacuum evaporation, sputtering, magnetron sputtering, chemical vapor deposition, or plasma-enhanced chemical vapor deposition.

6. The method of forming a self-rolled metallic nanosheet according to claim 1, wherein the swelling of the hydrogel layer to delaminate the metallic nanosheet comprises immersing the nanosheet-hydrogel-polymer composite in water.

7. The method of forming a self-rolled metallic nanosheet according to claim 1, wherein inducing channel cracks in the nanosheet-hydrogel-polymer composite comprises bending the composite around a roller.

8. The method of forming a self-rolled metallic nanosheet according to claim 1, wherein forming the hydrogel-based separation layer on the bendable polymeric substrate comprises spin-coating a hydrogel onto the bendable polymeric substrate.

9. A method of forming a self-rolled metallic nanosheet with a selected morphology comprising:
providing a bendable polymeric substrate;
forming a hydrogel-based separation layer on the bendable polymeric substrate;
depositing a thin-film metallic nanosheet on the hydrogel-based separation layer, the thin-film metallic nanosheet having a thickness of approximately 150 nm or less to form a nanosheet-hydrogel-polymer composite;
inducing channel cracks in the nanosheet-hydrogel-polymer composite having an inter-crack spacing of S;
swelling the hydrogel layer to delaminate the metallic nanosheet employing the induced channel cracks;
creating a helix morphology for relatively lower values of S and creating a scroll morphology for larger values of S.

10. The method of forming a self-rolled metallic nanosheet according to claim 9, wherein the bendable polymeric substrate is selected from polyimide, polyethylene terephthalate, nylon, or polyethylene.

11. The method of forming a self-rolled metallic nanosheet according to claim 9, wherein the hydrogel is selected from one or more of polyvinyl alcohol, silicone hydrogels, cellulose hydrogels, acrylate hydrogels, agarose, or chitosan.

12. The method of forming a self-rolled metallic nanosheet according to claim 9, wherein the metallic nanosheet is selected from titanium, titanium alloys, aluminum, aluminum alloys, vanadium, vanadium alloys, chromium, or chromium alloys.

13. The method of forming a self-rolled metallic nanosheet according to claim 9, wherein the metallic nanosheet is deposited by vacuum evaporation, sputtering, magnetron sputtering, chemical vapor deposition, or plasma-enhanced chemical vapor deposition.

14. The method of forming a self-rolled metallic nanosheet according to claim 9, wherein the swelling of the hydrogel layer to delaminate the metallic nanosheet comprises immersing the nanosheet-hydrogel-polymer composite in water.

15. The method of forming a self-rolled metallic nanosheet according to claim 9, wherein inducing channel cracks in the nanosheet-hydrogel-polymer composite comprises bending the composite around a roller.

16. The method of forming a self-rolled metallic nanosheet according to claim 1, wherein forming the hydrogel-based separation layer on the bendable polymeric substrate comprises spin-coating a hydrogel onto the bendable polymeric substrate.
